(19) United States
(12) Patent Application Publication
(10) Pub. No.: US 2026/0362754 A1
(43) Pub. Date: Nov. 12, 2026

(54) Quantum-Dot Qubit Device and Method of Manufacturing the Same

(71) Applicants: Samsung Electronics Co., Ltd., Suwon-si (KR); Seoul National University R&DB Foundation, Seoul (KR)

(72) Inventors: Ki Ho KIM, Suwon-si (KR); Dohun KIM, Suwon-si (KR); Geun Yong KIM, Suwon-si (KR); Hyo Won KIM, Suwon-si (KR); Shinwoo LEE, Suwon-si (KR); In Su JEON, Suwon-si (KR)

(73) Assignees: Samsung Electronics Co., Ltd., Suwon-si (KR); Seoul National University R&DB Foundation, Seoul (KR)

(21) Appl. No.: 18/598,268

(22) Filed: Mar. 7, 2024

(30) Foreign Application Priority Data
Nov. 14, 2023 (KR) 10-2023-0157584

(51) Int. Cl. H10D 48/00; G06N 10/40; H10D 48/01; H10D 62/83; H10D 64/27; H10W 10/10

(52) U.S. Cl. CPC H10D 48/383; G06N 10/40; H10D 48/031; H10D 62/83; H10D 64/518; H10D 64/519; H10W 10/181; H10D 48/3835

(57) ABSTRACT

A quantum-dot qubit device includes a channel, a plurality of plunger gate electrodes which are arranged at a predetermined interval at one end of an upper part of the channel, a plurality of barrier gate electrodes which are arranged at a predetermined interval at another end opposite to the one end, and a control circuit configured to form a plurality of quantum dot qubits via the plurality of plunger gate electrodes, and to control tunnel coupling between the quantum dot qubits by adjusting a barrier potential between the plunger gate electrodes by using the plurality of barrier gate electrodes.

### CROSS-REFERENCE TO RELATED APPLICATION(S)

This application claims the benefit under 35 USC § 119(a) of Korean Patent Application No. 10-2023-0157584 filed on Nov. 14, 2023 in the Korean Intellectual Property Office, the entire disclosure of which is incorporated herein by reference for all purposes.

### BACKGROUND

### 1. Field

The following description relates to a quantum-dot qubit device and a method of manufacturing the quantum-dot qubit device.

### 2. Description of the Related Art

A quantum computer may be a computational system that operates based on the principles of quantum mechanics, such as quantum superposition and quantum entanglement, for performing data processing. A unit element capable of storing information by using the principles of quantum mechanics or the information itself is called a quantum bit or qubit, which can be used as a basic unit of information in a quantum computer.

The qubits may be implemented as various types of qubits, such as photonic qubits, ion trap qubits, topological qubits, superconducting qubits, quantum dot qubits, etc., and in the quantum dot qubits quantum dots may be formed in a silicon semiconductor such that a semiconductor process can be used per se.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In one or more general aspects, a quantum-dot qubit device includes: a channel; a plurality of plunger gate electrodes which are arranged at a predetermined interval at one end of an upper part of the channel; a plurality of barrier gate electrodes which are arranged at a predetermined interval at another end opposite to the one end; and a control circuit configured to form a plurality of quantum dot qubits via the plurality of plunger gate electrodes, and to control tunnel coupling between the quantum dot qubits by adjusting a barrier potential between the plunger gate electrodes by using the plurality of barrier gate electrodes.

The plurality of plunger gate electrodes and the plurality of barrier gate electrodes may be disposed on a same plane.

The plurality of plunger gate electrodes and the plurality of barrier gate electrodes may be formed in such a manner that after a plurality of gate electrodes are formed on top of the channel, an etching process is performed at a predetermined position of the plurality of gate electrodes to separate each of the gate electrodes into the plunger gate electrode and the barrier gate electrode.

The plurality of plunger gate electrodes and the plurality of barrier gate electrodes may be arranged diagonally at a predetermined angle with respect to a longitudinal direction of the channel.

The predetermined angle may be determined based on a relationship between a thickness of either one or both of the plunger gate electrode and the barrier gate electrode, and a thickness of a portion removed from the channel by the etching process.

The predetermined angle may be 45 degrees.

The plurality of plunger gate electrodes and the plurality of barrier gate electrodes may be disposed such that each barrier gate electrode is disposed at a position facing a space between two successive plunger gate electrodes.

The plurality of plunger gate electrodes and the plurality of barrier gate electrodes may be disposed such that an upper end of the barrier gate electrode is disposed at a position facing a space between lower ends of the two successive plunger gate electrodes.

The plurality of plunger gate electrodes and the plurality of barrier gate electrodes may be disposed such that an upper end of the barrier gate electrode is disposed at a position facing a space between points where each of the two successive plunger gate electrodes meets one end of the channel.

The number of the plurality of plunger gate electrodes and the plurality of barrier gate electrodes may be 2N, wherein N is an integer greater than or equal to 2.

The plurality of plunger gate electrodes and the plurality of barrier gate electrodes may be disposed on top of a fully-depleted silicon-on-insulator (FDSOI).

The predetermined interval may be a center-to-center distance in a range of from 30 nm to 80 nm between the electrodes.

A thickness of the plunger gate electrode and the barrier gate electrode may range from 15 nm to 40 nm.

A vertical distance between the plunger gate electrode and the barrier gate electrode may range from 40 nm to 100 nm.

The control circuit may be configured to form the quantum dot qubits in a predetermined channel region which is located at a lower end of each plunger gate electrode.

In one or more general aspects, a method of manufacturing a quantum-dot qubit device includes: stacking a buried oxide layer on a fully-depleted silicon-on-insulator (FDSOI); stacking a channel on the buried oxide layer; forming a plurality of gate electrodes on top of the channel; performing an etching process at a predetermined position of the plurality of gate electrodes to separate each of the plurality of gate electrodes into two gate electrodes; determining one of the separated two gate electrodes to be a plunger gate electrode and a remaining one to be a barrier gate electrode; and forming a plurality of quantum dot qubits via the plurality of plunger gate electrodes.

The method may include controlling tunnel coupling between the quantum dot qubits by adjusting a barrier potential between the plunger gate electrodes by using the plurality of barrier gate electrodes.

The plurality of plunger gate electrodes and the plurality of barrier gate electrodes may be placed on a same plane.

The plurality of plunger gate electrodes and the plurality of barrier gate electrodes may be formed such that an upper end of the barrier gate electrode is disposed at a position facing a space between lower ends of two successive plunger gate electrodes.

In one or more general aspects, a quantum-dot qubit device includes: a channel; a plurality of plunger gate electrodes which are arranged at a predetermined interval at one end of an upper part of the channel; and a plurality of barrier gate electrodes which are arranged at a predetermined interval at another end opposite to the one end, wherein the plurality of plunger gate electrodes and the plurality of barrier gate electrodes are arranged diagonally at a predetermined angle with respect to a longitudinal direction of the channel.

Other features and aspects will be apparent from the following detailed description, the drawings, and the claims.

### BRIEF DESCRIPTION OF THE DRAWINGS

FIGS. 1A and 1B are plan views of a typical quantum-dot qubit device.

FIG. 1C is a diagram illustrating arrangement of gates in a typical quantum-dot qubit device.

FIG. 2 is a plan view of a quantum-dot qubit device according to one or more embodiments of the present disclosure.

FIG. 3A is a diagram illustrating arrangement of plunger gate electrodes and barrier gate electrodes according to one or more embodiments of the present disclosure.

FIG. 3B is a diagram illustrating arrangement of plunger gate electrodes and barrier gate electrodes according to one or more embodiments of the present disclosure.

FIG. 4A is a diagram illustrating a face-to-face structure in which plunger gate electrodes and barrier gate electrodes face each other.

FIG. 4B is a graph illustrating a change in barrier potential in a face-to-face structure.

FIG. 4C is a diagram illustrating a diagonal structure in which plunger gate electrodes and barrier gate electrodes are arranged diagonally at an angle according to one or more embodiments of the present disclosure.

FIG. 4D is a graph illustrating a change in barrier potential in a diagonal structure according to one or more embodiments of the present disclosure.

FIG. 5A is a graph illustrating a maximum barrier potential with respect to a barrier gate voltage in a face-to-face structure and a diagonal structure.

FIG. 5B is a graph illustrating tunneling speed between quantum dots with respect to a barrier gate voltage in a face-to-face structure and a diagonal structure.

FIG. 6 is a flowchart illustrating a method of manufacturing a quantum-dot qubit device according to one or more embodiments of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

In the following description, when an element is referred to as being “above” or “below” another element, it may be directly above or below the other element while being in contact with the other element, but it may also be above or below the element without contact with the other element.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The steps of all methods described herein can be performed in any suitable order unless otherwise indicated herein or otherwise clearly contradicted by context. The use of any and all examples, or language (e.g., such as, etc.) provided herein, is intended merely to better illuminate the disclosure and does not pose a limitation on the scope of the disclosure unless otherwise claimed.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

A quantum dot is a three-dimensional isolated structure in which an electron or a hole is spatially confined in the quantum dot due to the quantum confinement effect. The quantum dot forms discrete energy levels and may be represented as a nanoscale potential well.

A quantum dot qubit is a quantum dot defined as a qubit, in which among discrete quantum states of the quantum dot, two quantum states, e.g., spin-up and spin-down states of one electron in a quantum dot, may be selected in the quantum dot qubit.

A quantum-dot qubit device may be a device with quantum dots formed in a silicon semiconductor, such that the quantum-dot qubit device may have a similar structure to a field effect transistor (FET). The quantum-dot qubit device may form quantum dots in a channel by adjusting a gate voltage, and may perform quantum calculations by using superposition of spin states of an electron or a hole in the quantum dot or entanglement between adjacent qubits.

In order for the quantum-dot qubit device to perform quantum calculations, multiple quantum dots may be formed and a plurality of plunger gate electrodes and barrier gate electrodes may be formed for spin control. The quantum-dot qubit device is highly compatible with an existing complementary metal-oxide semiconductor (CMOS) process, thereby facilitating production of large-scale integrated quantum processors.

The quantum-dot qubit device may control tunnel coupling by adjusting a barrier potential between plunger gate electrodes, i.e., quantum dots, by using barrier gate electrodes, thereby allowing rapid control during two-qubit gate operations using quantum entanglement, while being highly resistant to charge noise.

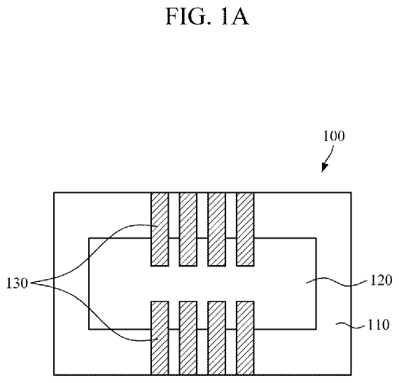

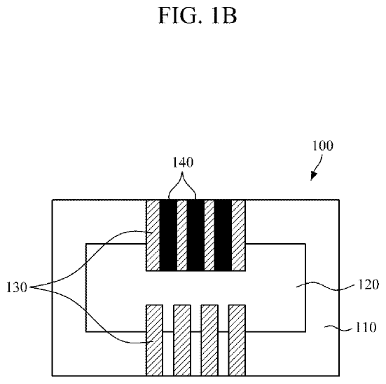

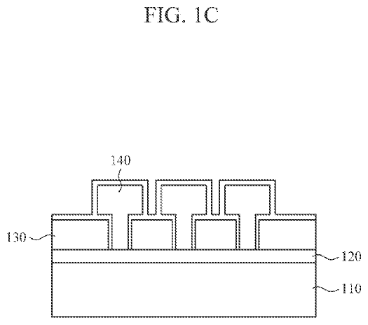

FIGS. 1A and 1B are plan views of a typical quantum-dot qubit device. FIG. 1C is a diagram illustrating arrangement of gates in a typical quantum-dot qubit device.

Referring to FIG. 1A, a buried Oxide (BOX) layer 110 made of, for example, silicon dioxide (SiO₂), and a channel 120 made of silicon (Si) may be stacked in a quantum-dot qubit device 100, and plunger gate electrodes 130 for forming quantum dot qubits may be placed on top of the channel 120.

Referring to FIGS. 1B and 1C, in the quantum dot qubits on silicon (Si), it may be required to set a distance (pitch) of 100 nm or less between quantum dots, since sufficient tunnel coupling between the quantum dots is required for two-qubit gate operations.

Due to a small distance between the quantum dots, the barrier gate electrodes 140 are typically placed on top of the plunger gate electrodes 130 in a top gate manner (e.g., as shown in FIG. 1C).

However, in the typical quantum-dot qubit device, the top-gate electrode structure has a problem in that the structure may limit a fully depleted silicon-on-insulator (FDSOI) process used for production of large-scale quantum processor devices. Further, in the typical quantum-dot qubit device, it may also be difficult to accurately place a plurality of barrier gate electrodes between plunger gate electrodes spaced at intervals of several tens of nanometers (nm), and even in the case of using a method of controlling barrier potential by using a back gate, the use of back gate may make it difficult to control the barrier potential between qubits.

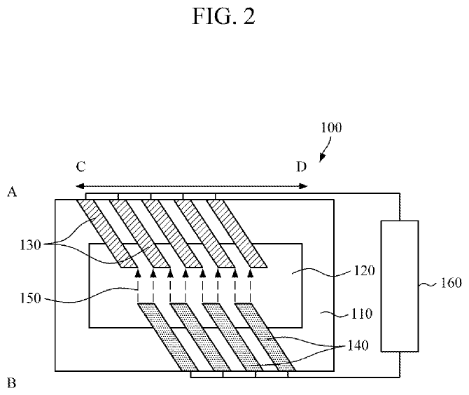

FIG. 2 is a plan view of a quantum-dot qubit device according to one or more embodiments of the present disclosure.

Referring to FIG. 2, a substrate (not shown), a buried oxide layer 110, and a channel 120 may be stacked in the quantum-dot qubit device 100, in which a plurality of plunger gate electrodes 130 may be arranged at a predetermined interval at one end A of an upper part of the channel 120, and a plurality of barrier gate electrodes 140 may be arranged at a predetermined interval at another end B opposite to the one end A.

In this example, in the quantum-dot qubit device 100, a fully depleted silicon-on-insulator (FDSOI), in which almost no neutral body region exists, may be used as a wafer at an upper end of the buried oxide layer, and thus the plunger gate electrodes 130 and the barrier gate electrodes may also be formed on top of the FDSOI.

In addition, a control circuit 160 may be connected to the electrodes in the device to drive the quantum-dot qubit device 100.

For example, the control circuit 160 may form a plurality of quantum dot qubits via the plurality of plunger gate electrodes 130, and may control tunnel coupling between the formed quantum dot qubits by adjusting the barrier potential between the plunger gate electrodes, e.g., quantum dots, using the plurality of barrier gate electrodes 140.

The plunger gate electrodes 130 may be gates for forming quantum dots on the channel, and the control circuit 160 may control the formation of quantum dot qubits in a predetermined region of the channel 120 at a lower end of each plunger gate electrode 130, e.g., at the upper portion of the channel 120 in contact with the plunger gate electrodes 130.

The barrier gate electrodes 140 may be gate electrodes for formation of exchange interactions between quantum dots for two-qubit gate operations, in which the control circuit 160 may adjust the barrier potential, which is a potential difference required for electromigration, by using the barrier gate electrodes 140 to control tunnel coupling for performing quantum entanglement between the quantum dot qubits.

In this example, in order to expand the number of qubits, there may be a plurality of plunger gate electrodes and barrier gate electrodes, and the number of each of the plunger and barrier gate electrodes may be greater than or equal to 2N (N being an integer greater than or equal to 2). However, the number of the electrodes is not limited thereto.

The plunger gate electrodes 130 and the barrier gate electrodes 140 may be deposited on top of the channel 120, in which after a plurality of gate electrodes are first formed on top of the channel 120, the plurality of gate electrodes may be spatially separated by an etching process performed at a predetermined position of the plurality of gate electrodes, such that each of the separated electrodes may be formed as the plunger gate electrode 130 and the barrier gate electrode 140.

As described above, after the electrodes are formed on top of the channel 120, the etching process may be performed to separate each electrode into the plunger gate electrode 130 and the barrier gate electrode 140, such that the two gate electrodes may be placed on the same plane instead of multiple layers in a typical top-gate structure.

In this example, in order for the control circuit 160 to efficiently control the barrier potential between the quantum dot qubits, the plurality of plunger gate electrodes and barrier gate electrodes may be arranged diagonally at a predetermined angle with respect to a longitudinal direction (C-D direction) of the channel 120, and each barrier gate electrode may be disposed at a position 150 facing a space between two successive plunger gate electrodes.

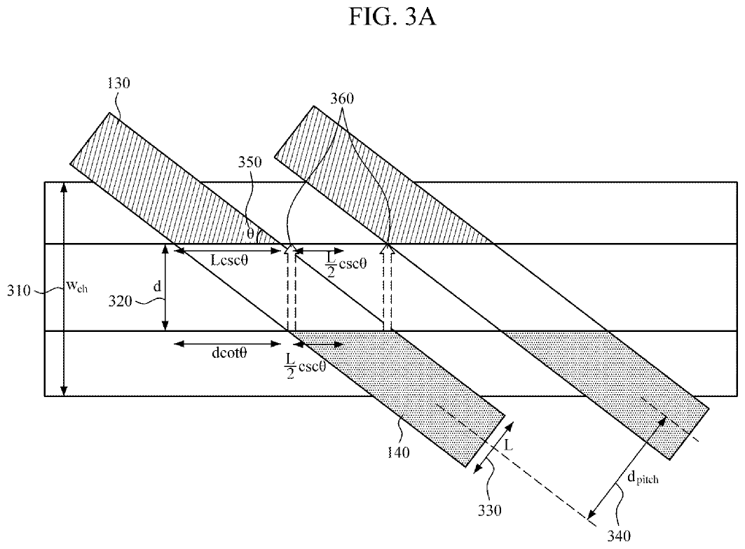

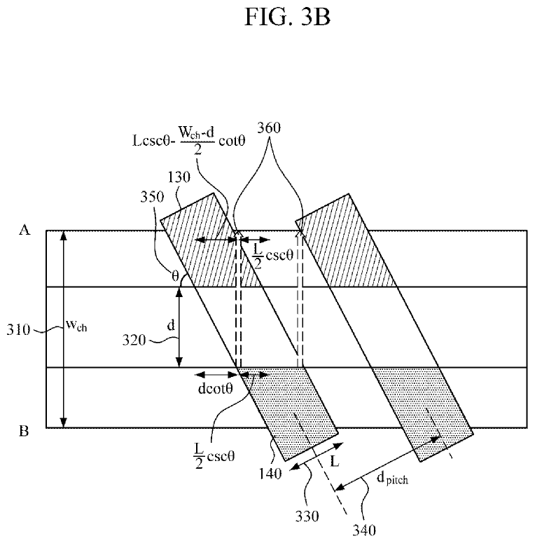

FIG. 3A is a diagram illustrating arrangement of plunger gate electrodes and barrier gate electrodes according to one or more embodiments of the present disclosure.

Referring to FIG. 3A, when a center-to-center distance d_{pitch} 340 between the gate electrodes corresponds to, for example, twice a thickness L 330 of the gate electrode, Equation 1 below, for example, may be satisfied, and a length d of a portion removed by the etching process may be expressed in Equation 2 below, for example, by Equation 1.

$$L csc θ + \frac{L}{2} csc θ = d cot θ + \frac{L}{2} csc θ \qquad Equation 1$$

$$d = L sec θ \qquad Equation 2$$

Herein, θ 350 (e.g., 45 degrees) denotes an angle in a diagonal direction with respect to a longitudinal direction of the channel, and may be determined based on a relationship between the thickness L of the plunger gate electrode 130 or the barrier gate electrode 140 and a thickness d of the portion removed from the channel by the etching process.

When a thickness W_{ch} 310 of the channel is in a range of from 20 nm to 100 nm, the center-to-center distance d_{pitch} 340 between the plunger gate electrodes 130 and the center-to-center distance d_{pitch} 340 between the plunger gate electrodes 130 may be in a range of from 30 nm to 80 nm. In addition, the thickness L 330 of the plunger gate electrode 130 and the barrier gate electrode 140 may be in a range of from 15 nm to 40 nm. Further, a vertical distance between the plunger gate electrode 130 and the barrier gate electrode 140 may be in a range of from 40 nm to 100 nm. However, the center-to-center distance, the thickness, and the vertical distance are not limited thereto.

In addition, each of the barrier gate electrodes 140 may be disposed at a position 360 facing a space between two plunger gate electrodes 130. In this arrangement, the controlled potential barrier between the quantum dot qubits may be located closer to the barrier gate electrode 140, and a distance between the potential barrier and other quantum dot qubits relatively increases, such that barrier potential between the qubits may be effectively controlled.

FIG. 3B is a diagram illustrating arrangement of plunger gate electrodes and barrier gate electrodes according to one or more embodiments of the present disclosure.

Referring to FIG. 3B, in the plurality of plunger gate electrodes 130 and barrier gate electrodes 140, an upper end of the barrier gate electrode 140 may be disposed at a position 360 facing a space between points where each of two successive plunger gate electrodes 130 meets one end A of the channel.

In this example, when the center-to-center distance d_{pitch} 340 between the gate electrodes corresponds to twice the thickness L 330 of the gate electrode, Equation 3 below, for example, may be satisfied, and the length d of a portion removed by the etching process may be expressed in Equation 4 below, for example, by Equation 3.

$$L csc θ - \frac{{W}_{ch} - d}{2} cot θ + \frac{L}{2} csc θ = d cot θ + \frac{L}{2} csc θ \qquad Equation 3$$

$$d = 2 L sec θ - {W}_{ch} \qquad Equation 4$$

Herein, θ 350 denotes an angle in a diagonal direction with respect to a longitudinal direction of the channel, and may be determined based on a relationship between the thickness L 330 of the plunger gate electrode 130 or the barrier gate electrode 140, a thickness d 320 of the portion removed from the channel by the etching process, and the thickness W_{ch} 310 of the channel.

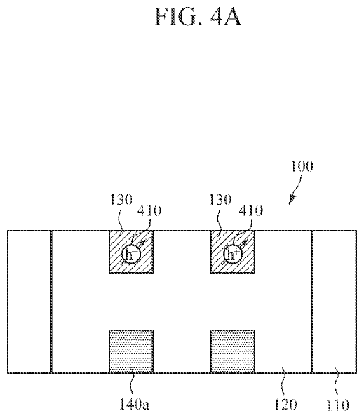

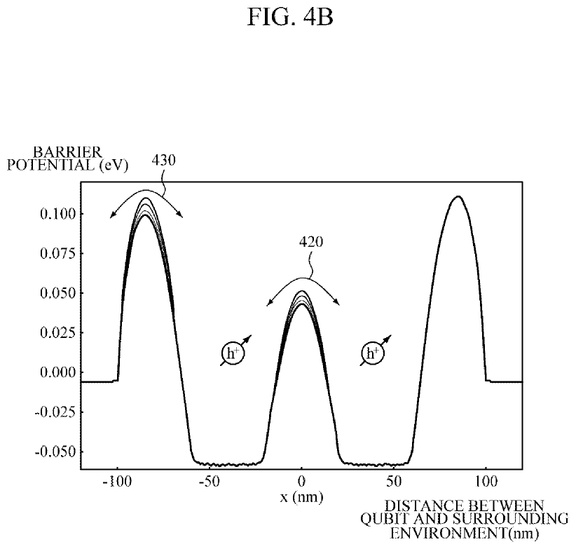

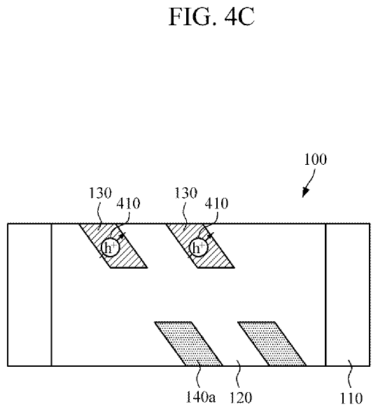

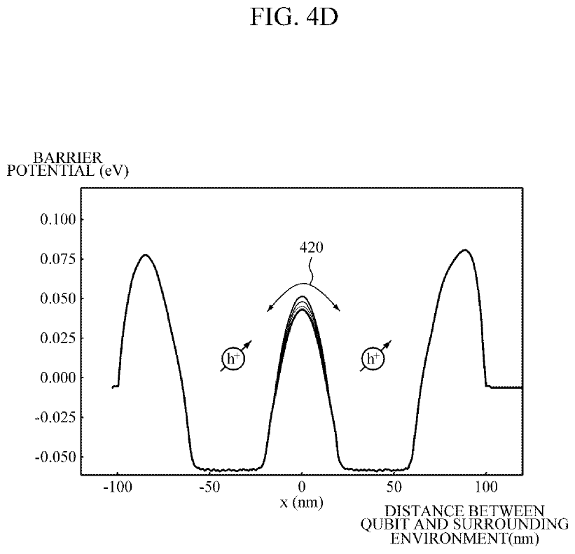

FIG. 4A is a diagram illustrating a face-to-face structure in which plunger gate electrodes and barrier gate electrodes face each other, and FIG. 4B is a graph illustrating a change in barrier potential in the face-to-face structure.

Referring to FIGS. 4A and 4B, when a control circuit of a typical quantum-dot qubit device with the face-to-face structure controls the barrier potential between two quantum dots 410, formed under the plunger gate electrodes 130, by using the barrier gate electrodes 140a, not only is a barrier potential 420 formed between the two quantum dots 410 but also a barrier potential 430 in an undesired region is formed between other quantum dots, such that the barrier potentials 420 and 430 are both controlled in the face-to-face structure, such that the performance of controlling inter-qubit tunnel coupling may be reduced.

FIG. 4C is a diagram illustrating a diagonal structure in which plunger gate electrodes and barrier gate electrodes are arranged diagonally at an angle according to one or more embodiments of the present disclosure, and FIG. 4D is a graph illustrating a change in barrier potential in the diagonal structure according to one or more embodiments of the present disclosure.

Referring to FIGS. 4C and 4D, in contrast to the typical quantum-dot qubit device, when the control circuit 160 of the quantum-dot qubit device 100 of one or more embodiments controls the barrier potential between two quantum dots 410, formed under the plunger gate electrodes 130, by using the barrier gate electrodes 140a, the barrier potential 420 is formed between the two quantum dots 410 but the barrier potential 430 is not formed, such that only the barrier potential 420 between the two quantum dots 410 is controlled in the diagonal structure, such that the performance of controlling inter-qubit tunnel coupling may be improved.

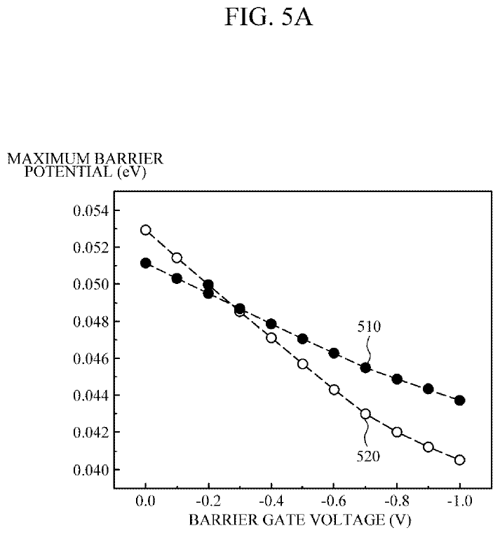

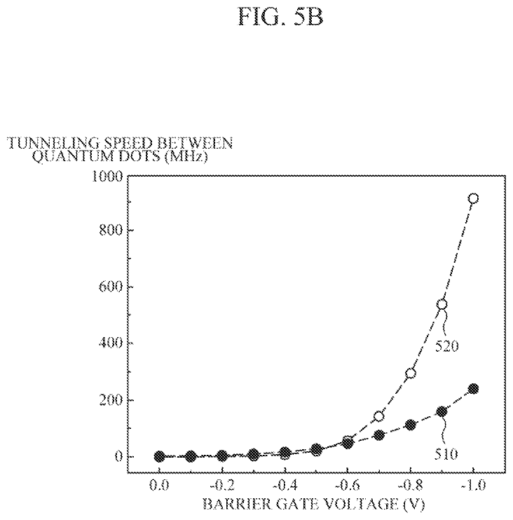

FIG. 5A is a graph illustrating a maximum barrier potential with respect to a barrier gate voltage in a typical face-to-face structure and diagonal structure, and FIG. 5B is a graph illustrating tunneling speed between quantum dots with respect to a barrier gate voltage in the face-to-face structure and diagonal structure.

Referring to FIGS. 5A and 5B, it can be seen that a change in maximum barrier potential with respect to the barrier gate voltage is greater in the diagonal structure 520 than in the face-to-face structure 510, such that even at a same small voltage, a tunneling speed between quantum dots is greater in the diagonal structure 520 than in the face-to-face structure 510, such that the diagonal structure 520 of one or more embodiments is more effective for two-qubit gate operations than the face-to-face structure 510.

Typically, in the top-gate electrode structure used for the quantum-dot qubit device, the barrier potential between qubits may not be easily adjusted, and it may be difficult to accurately place a plurality of barrier gate electrodes between plunger gate electrodes spaced at intervals of several tens of nanometers (nm). However, in the quantum-dot qubit device 100 of one or more embodiments in which the plunger gate electrodes and the barrier gate electrodes are diagonally arranged on the same plane, the quantum-dot qubit device 100 may be easily manufactured by the FDSOI process, and the barrier potential between the quantum dot qubits may be efficiently controlled.

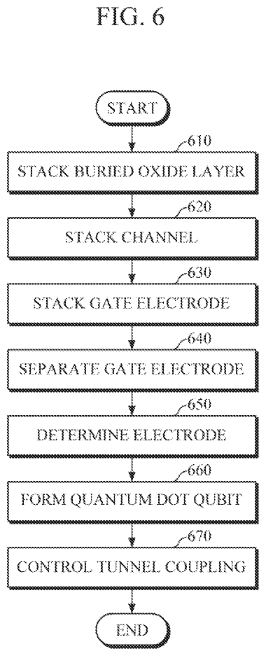

FIG. 6 is a flowchart illustrating a method of manufacturing a quantum-dot qubit device according to one or more embodiments of the present disclosure. Operations 610 to 670 described below may be performed in the order and manner as shown and described below with reference to FIG. 6, but the order of one or more of the operations may be changed, one or more of the operations may be omitted, and/or two or more of the operations may be performed in parallel or simultaneously without departing from the spirit and scope of the example embodiments described herein.

The method of FIG. 6 is an example of a method of manufacturing the quantum-dot qubit devices of FIGS. 2 to 5B, and thus will be briefly described below in order to avoid redundancy.

The buried oxide layer may be stacked on the fully-depleted silicon on insulator (FDSOI) in 610, the channel may be stacked on the buried oxide layer in 620, and the plurality of gate electrodes may be formed on top of the channel in 630.

The etching process may be performed at a predetermined position of the plurality of gate electrodes to separate each of the plurality of gate electrodes into two gate electrodes in 640.

One of the separated two gate electrodes may be determined to be a plunger gate electrode and a remaining one may be determined to be a barrier gate electrode in 650.

In this example, by the etching process, the plurality of plunger gate electrodes and barrier gate electrodes may be placed on the same plane. In addition, an upper end of the barrier gate electrode may be disposed at a position facing a space between lower ends of two successive plunger gate electrodes, and an upper end of the barrier gate electrode may also be disposed at a position facing a space between points where each of two successive plunger gate electrodes meets one end of the channel.

A plurality of quantum dot qubits may be formed via the plurality of plunger gate electrodes in 660.

Tunnel coupling between the quantum dot qubits may be controlled by adjusting the barrier potential between the plunger gate electrodes by using the plurality of barrier gate electrodes in 670.

The quantum-dot qubit devices, BOX layers, channels, plunger gate electrodes, barrier gate electrodes, control circuits, quantum-dot qubit device 100, BOX layer 110, channel 120, plunger gate electrodes 130, barrier gate electrodes 140, control circuit 160, barrier gate electrodes 140a described herein, including descriptions with respect to respect to FIGS. 1A-6, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1A-6 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROM, DVD-Rs, DVD+Rs, DVD-RWs, DVD+RW, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A quantum-dot qubit device comprising:
a channel;
a plurality of plunger gate electrodes which are arranged at a predetermined interval at one end of an upper part of the channel;
a plurality of barrier gate electrodes which are arranged at a predetermined interval at another end opposite to the one end; and
a control circuit configured to form a plurality of quantum dot qubits via the plurality of plunger gate electrodes, and to control tunnel coupling between the quantum dot qubits by adjusting a barrier potential between the plunger gate electrodes by using the plurality of barrier gate electrodes.

2. The quantum-dot qubit device of claim 1, wherein the plurality of plunger gate electrodes and the plurality of barrier gate electrodes are disposed on a same plane.

3. The quantum-dot qubit device of claim 2, wherein the plurality of plunger gate electrodes and the plurality of barrier gate electrodes are formed in such a manner that after a plurality of gate electrodes are formed on top of the channel, an etching process is performed at a predetermined position of the plurality of gate electrodes to separate each of the gate electrodes into the plunger gate electrode and the barrier gate electrode.

4. The quantum-dot qubit device of claim 1, wherein the plurality of plunger gate electrodes and the plurality of barrier gate electrodes are arranged diagonally at a predetermined angle with respect to a longitudinal direction of the channel.

5. The quantum-dot qubit device of claim 4, wherein the predetermined angle is determined based on a relationship between a thickness of either one or both of the plunger gate electrode and the barrier gate electrode, and a thickness of a portion removed from the channel by the etching process.

6. The quantum-dot qubit device of claim 5, wherein the predetermined angle is 45 degrees.

7. The quantum-dot qubit device of claim 5, wherein the plurality of plunger gate electrodes and the plurality of barrier gate electrodes are disposed such that each barrier gate electrode is disposed at a position facing a space between two successive plunger gate electrodes.

8. The quantum-dot qubit device of claim 7, wherein the plurality of plunger gate electrodes and the plurality of barrier gate electrodes are disposed such that an upper end of the barrier gate electrode is disposed at a position facing a space between lower ends of the two successive plunger gate electrodes.

9. The quantum-dot qubit device of claim 7, wherein the plurality of plunger gate electrodes and the plurality of barrier gate electrodes are disposed such that an upper end of the barrier gate electrode is disposed at a position facing a space between points where each of the two successive plunger gate electrodes meets one end of the channel.

10. The quantum-dot qubit device of claim 1, wherein the number of the plurality of plunger gate electrodes and the plurality of barrier gate electrodes is 2N, wherein N is an integer greater than or equal to 2.

11. The quantum-dot qubit device of claim 1, wherein the plurality of plunger gate electrodes and the plurality of barrier gate electrodes are disposed on top of a fully-depleted silicon-on-insulator (FDSOI).

12. The quantum-dot qubit device of claim 1, wherein the predetermined interval is a center-to-center distance in a range of from 30 nm to 80 nm between the electrodes.

13. The quantum-dot qubit device of claim 1, wherein a thickness of the plunger gate electrode and the barrier gate electrode ranges from 15 nm to 40 nm.

14. The quantum-dot qubit device of claim 1, wherein a vertical distance between the plunger gate electrode and the barrier gate electrode ranges from 40 nm to 100 nm.

15. The quantum-dot qubit device of claim 1, wherein the control circuit is configured to form the quantum dot qubits in a predetermined channel region which is located at a lower end of each plunger gate electrode.

16. A method of manufacturing a quantum-dot qubit device, the method comprising:
stacking a buried oxide layer on a fully-depleted silicon-on-insulator (FDSOI);
stacking a channel on the buried oxide layer;
forming a plurality of gate electrodes on top of the channel;
performing an etching process at a predetermined position of the plurality of gate electrodes to separate each of the plurality of gate electrodes into two gate electrodes;
determining one of the separated two gate electrodes to be a plunger gate electrode and a remaining one to be a barrier gate electrode; and
forming a plurality of quantum dot qubits via the plurality of plunger gate electrodes.

17. The method of claim 16, further comprising controlling tunnel coupling between the quantum dot qubits by adjusting a barrier potential between the plunger gate electrodes by using the plurality of barrier gate electrodes.

18. The method of claim 17, wherein the plurality of plunger gate electrodes and the plurality of barrier gate electrodes are placed on a same plane.

19. The method of claim 16, wherein the plurality of plunger gate electrodes and the plurality of barrier gate electrodes are formed such that an upper end of the barrier gate electrode is disposed at a position facing a space between lower ends of two successive plunger gate electrodes.

20. A quantum-dot qubit device comprising:
a channel;
a plurality of plunger gate electrodes which are arranged at a predetermined interval at one end of an upper part of the channel; and
a plurality of barrier gate electrodes which are arranged at a predetermined interval at another end opposite to the one end,
wherein the plurality of plunger gate electrodes and the plurality of barrier gate electrodes are arranged diagonally at a predetermined angle with respect to a longitudinal direction of the channel.
